(19) United States
(12) Patent Application Publication
(10) Pub. No.: US 2025/0038005 A1
(43) Pub. Date: Jan. 30, 2025

(54) SEMICONDUCTOR DEVICE MANUFACTURING METHOD AND SEMICONDUCTOR MANUFACTURING APPARATUS

(71) Applicant: HITACHI HIGH-TECH CORPORATION, Minato-ku, Tokyo (JP)

(72) Inventor: Yoshihide YAMAGUCHI, Tokyo (JP)

(21) Appl. No.: 18/280,578

(22) PCT Filed: Aug. 23, 2022
(86) PCT No.: PCT/JP2022/031666

§ 371 Date: Sep. 6, 2023

(51) Int. Cl. H01L 21/311; H01J 37/32; H01L 21/66; H01L 21/67

(52) U.S. Cl. CPC H01L 21/31122; H01J 37/32449; H01L 21/67115; H01L 22/12; H01J 2237/3341; H01J 2237/3346

(57) ABSTRACT

An objective of the present invention is to provide a method of manufacturing a semiconductor device and a semiconductor manufacturing apparatus that can ensure treatment efficiency and suppress the occurrence of foreign matters, without requiring a complicated gas supplying system. One representative method, according to the present invention, of manufacturing a semiconductor device includes a step of comparing a remaining amount of processing for a film to be treated that is formed on a semiconductor wafer, with a threshold, a step of forming a compound made from the film to be treated and an organic gas by heating the semiconductor wafer while supplying the organic gas, the organic gas including a material having, within a molecule, at least two substituents that hold a lone pair, and a step of causing the compound to desorb from a surface of the semiconductor wafer by, on the basis of a result of the comparing, further heating the semiconductor wafer after the step of forming the compound, to raise a temperature of the semiconductor wafer to a predetermined temperature.

### TECHNICAL FIELD

The present invention pertains to a method of manufacturing a semiconductor device, and pertains to a semiconductor manufacturing apparatus.

### BACKGROUND ART

There are more and more demands to make cutting-edge semiconductor devices be smaller, be faster, have higher performance, and have lower power consumption. Application of new materials is progressing, and there are demands for nanometer-level very-high precision processing (for example, film formation and etching) of these materials.

As an example of such a technique, a technique disclosed in JP-2018-500767-T (Patent Literature 1) is known heretofore. In the technique disclosed in Patent Literature 1, in order to process an Al₂O₃ film, an HfO₂ film, or a ZrO₂ film at the very-high precision of an atomic-layer-level, a reactive gas that includes a halogen such as F (fluorine) is reacted with a film to be processed, to convert the film to a fluoride, and then, the fluoride is reacted with an organometallic compound that is to be a ligand exchange agent, to be converted to an organometallic complex having volatility, thereby volatilizing and removing the organometallic complex. More specifically, in the case of an Al₂O₃ film, the film is reacted with a reactive gas that includes F, to perform a conversion to AlFₓ (a fluoride), and is then reacted with trialkylaluminum which is a ligand exchange agent, to convert the film to Al(CH₃)Fₓ₋₁. Then, Al(CH₃)Fₓ₋₁ is removed by being volatilized under heating to 200° C. to 300° C. By such a series of treatments, the Al₂O₃ film is subjected to atomic-layer-level high-accuracy etching.

### PRIOR ART DOCUMENT

### Patent Document

Patent Document 1: JP-2018-500767-T

### Non-Patent Document

Non-Patent Document 1: Younger Lee and Steven M. George, Journal of Vacuum Science & Technology A 36(6) 061504 (2018)

### SUMMARY OF THE INVENTION

### Problems to be Solved by the Invention

In a course of considering nanometer-level ultra-high-precision processing of material that includes various elements, the inventors of the present application have advanced consideration from a perspective of application to a multilayer film resulting from laminating many types of materials. As a result of such consideration, the inventors have determined that there is a demand for an etching technique capable of being performed under a condition of relatively low temperatures, from a perspective of preventing interlayer diffusion in the multilayer film.

Patent Literature 1 described above is considered as a promising technique from a perspective of being able to perform selective etching at equal to or less than 400° C. However, as a result of examination, it is found that there is room for improve regarding the following points.

Specifically, because two entirely different types of gases, i.e., a reactive gas that includes F and a ligand exchange agent, are used, there is a risk that a gas supplying system for supplying the gas and control of the system will become complicated and that an etching treatment apparatus will increase in size or become expensive.

In addition, in the interval between a treatment using a reactive gas that contains F and a treatment using a ligand exchange agent, there is a need to provide a period for halting a reaction by performing a gas exchange within a chamber, in order to prevent the two types of gases from mixing. Moreover, it is also necessary to provide a reaction induction period after a first reaction is halted until a second reaction starts. In this manner, it is not possible to immediately start the second reaction even if supplying of the second gas starts after supplying of the first gas is stopped. As a result, there is a risk that a cycle time will lengthen and that etching efficiency will decrease.

In addition, an organometallic complex that has volatility and that is generated by a ligand exchange reaction is normally not very thermally stable. Accordingly, in a period of time from volatilization of the organometallic complex from the wafer surface until discharge from the chamber, there is a risk that part of the organometallic complex will undergo thermal decomposition to become a foreign matter, stay within the treatment chamber, and re-adhere to the wafer surface. Such problems as described above are not sufficiently considered in the conventional technique described above.

An objective of the present invention is to provide a method of manufacturing a semiconductor device and a semiconductor manufacturing apparatus that can ensure treatment efficiency and suppress the occurrence of foreign matters, without requiring a complicated gas supplying system.

### Means for Solving the Problems

In order to solve the problems described above, one representative method, according to the present invention, of manufacturing a semiconductor device includes a step of comparing a remaining amount of processing for a film to be treated that is formed on a semiconductor wafer, with a threshold, a step of forming a compound made from the film to be treated and an organic gas by heating the semiconductor wafer while supplying the organic gas, the organic gas including a material having, within a molecule, at least two substituents that hold a lone pair, and a step of causing the compound to desorb from a surface of the semiconductor wafer by, on the basis of a result of the comparing, further heating the semiconductor wafer after the step of forming the compound, to raise a temperature of the semiconductor wafer to a predetermined temperature.

In addition, one representative semiconductor manufacturing apparatus according to the present invention includes a vacuum container having a treatment chamber therein, a stage that is disposed within the treatment chamber and that has a top surface on which a semiconductor wafer having, on a surface thereof, a film to be treated is placed, a treatment gas supply device configured to supply an organic gas into the treatment chamber, an exhaust device configured to exhaust the gas inside the treatment chamber, a heater configured to heat the semiconductor wafer to raise a temperature of the semiconductor wafer to a predetermined temperature, and a control unit. The organic gas has, within a molecule, at least two substituents that hold a lone pair. The control unit controls a step of comparing a remaining amount of processing for the film to be treated, with a threshold, a step of forming a compound made from the film to be treated and the organic gas by heating the semiconductor wafer while supplying the organic gas to the treatment chamber, the organic gas including a material having, within a molecule, at least two substituents that hold a lone pair, and a step of causing the compound to desorb from the surface of the semiconductor wafer by, on the basis of a result of the step of comparing, further heating the semiconductor wafer after the step of forming the compound, to raise the temperature of the semiconductor wafer to the predetermined temperature.

### Advantages of the Invention

According to the present invention, it is possible to provide a method of manufacturing a semiconductor device and a semiconductor manufacturing apparatus that can ensure treatment efficiency and suppress the occurrence of foreign matters, without requiring a complex gas supplying system.

### BRIEF DESCRIPTION OF THE DRAWINGS

FIG. 1 is a view that schematically illustrates a configuration of a semiconductor manufacturing apparatus according to an embodiment of the present invention.

FIG. 2 is a flow chart that illustrates a wafer treatment performed in the semiconductor manufacturing apparatus.

FIG. 3 illustrates a time chart for steps B that include steps S103B through S106B.

FIG. 4 illustrates a time chart for steps A that include steps S103A through S107A.

FIG. 5 is a view that illustrates a time chart for a modification performed in the semiconductor manufacturing apparatus.

FIG. 6 is a view that illustrates a molecular structure of components of a complexing gas.

### MODE FOR CARRYING OUT THE INVENTION

The inventors have discovered a phenomenon in which an organometallic complex having high thermal stability and high volatility is generated in one step by exposing a film to be etched to an organic gas having electron-donating atoms at at least two locations within a molecule thereof. The inventors have obtained findings that it is possible to use this phenomenon to achieve high-efficiency etching.

In an organic gas that includes an organic compound having electron-donating atoms at at least two locations within a molecule thereof, the electron-donating atoms donate electrons to positive charges belonging to metal elements within the film to be etched, whereby a thermally stable organometallic complex having electron-donating and back-donating strong coordinate bonds is formed. The present invention employs such an organometallic complex, whereby it is possible to resolve thermal instability of organometallic complexes, which is a problem in conventional techniques.

In addition, inside an organometallic complex according to an embodiment, positive charges belonging to metal elements within the film to be etched are neutralized in terms of electric charge by electrons donated from the electron-donating atoms at two locations within the etching gas. With charge neutralization being performed in this manner, electrostatic chucking acting between adjacent molecules is extinguished, and volatility (sublimability) of the organometallic complex is improved. Moreover, because it is possible to generate an organometallic complex having high volatility in one step of exposing a film to be etched to an organic gas, provision of a reaction downtime, which is employed in conventional techniques, is not needed. As a result, it is also possible to avoid reducing etching efficiency.

### EMBODIMENT

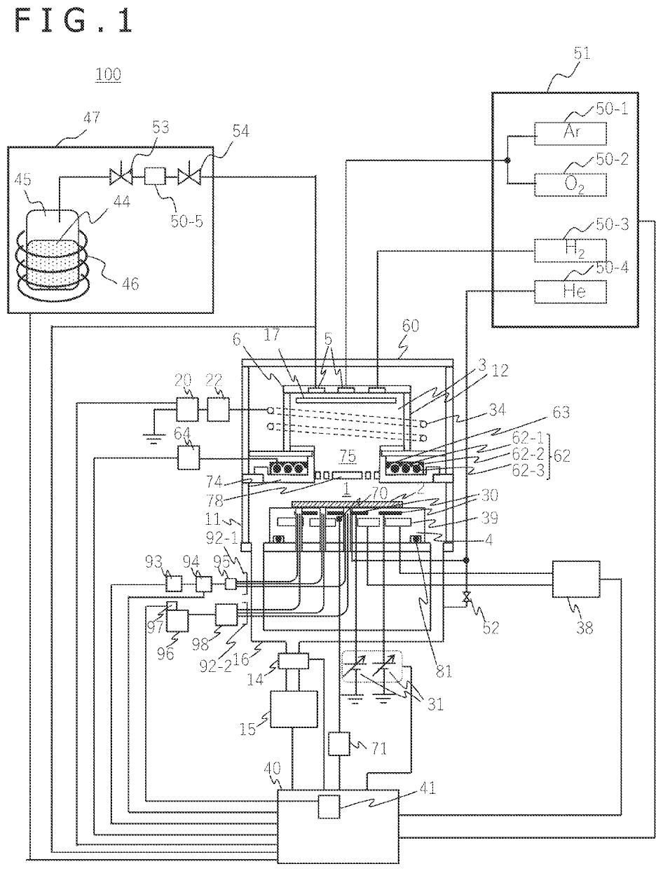

An embodiment of the present invention will be described below with reference to FIG. 1 through FIG. 6. Note that the present invention is not limited to the embodiment.

### (Apparatus Configuration)

FIG. 1 is a view that schematically illustrates a configuration of a semiconductor manufacturing apparatus according to an embodiment of the present invention.

A treatment chamber 1 includes a base chamber 11 which is a cylindrical metal container. In the base chamber 11, a wafer stage (hereinafter, will also be referred to as a “stage”) 4 for placing a semiconductor wafer (hereinafter, will also be referred to as a “wafer”) 2 that is a sample to be treated is installed. In order to generate a plasma by using an ICP (Inductive Coupled Plasma) discharge method, a quartz chamber 12, an ICP coil 34 disposed outside of the quartz chamber 12, and a plasma generator including a high-frequency power supply 20 are provided on the upper side of the treatment chamber 1.

Note that the present invention does not necessarily need to use ICP plasma, and the present invention can also employ a configuration in which a plasma generator is omitted. However, in steps before or after treatment that is a target of the present invention, it is envisioned that a process that uses ICP plasma, such as an ALD (Atomic Layer Deposition) treatment for laminating every atomic layer or a Plasma-ALE (Plasma Enhanced Atomic Layer Etching) treatment, is performed. Accordingly, as illustrated in FIG. 1, a configuration that includes an ICP plasma generator is described herein.

The high-frequency power supply 20 for generating plasma is connected to the ICP coil 34 via a matcher 22, and a frequency band of several tens of MHz is used for the frequency of the high-frequency power supply 20. A top plate 6, a shower plate 5, and a gas dispersion plate 17 are provided at the top of the quartz chamber 12. Gas (treatment gas) supplied for the treatment of the wafer 2 is introduced to the treatment chamber 1 through a gap in the outer periphery of the gas dispersion plate 17.

In the present embodiment, a flow rate of the treatment gas is adjusted by using mass flow controllers 50-1 through 50-3 disposed within an integrated mass flow controller control unit 51. The treatment gas includes a plurality of gas species, and the mass flow controllers 50-1 through 50-3 are provided for the corresponding gas species. In FIG. 1, supplying of three types of treatment gas, i.e., Ar, O₂, and H₂, is controlled by the corresponding mass flow controllers 50-1, 50-2, and 50-3. For example, a mass flow controller corresponding to any of other treatment gases, e.g., a halogen organic gases such as hydrofluorocarbons CHF, or chlorocarbons CHClₓ or non-halogen organic gases such as CH₄ or CH₃OCH₃, may additionally be provided for each gas species. Note that the integrated mass flow controller control unit 51 in FIG. 1 also includes a mass flow controller 50-4 for adjusting the flow rate of an He cooling gas that is fed between a back surface of the wafer 2 and a top surface of a dielectric film on a stage 4 on which the wafer 2 is placed. The mass flow controller 50-4 may be provided separately from the integrated mass flow controller control unit 51.

In the present embodiment, an organic gas is used as at least part of the treatment gas. The organic gas can be obtained by vaporizing a liquid raw material with the use of an organic gas vaporizer supply device 47.

A tank 45 for accommodating a chemical liquid 44 that is the liquid raw material is provided inside the organic gas vaporizer supply device 47. The chemical liquid 44 is heated by a heater 46 provided around the tank 45, and vapor from the chemical liquid 44 fills an upper portion of the tank 45. An atomizer or bubbler may be installed if necessary. In such a case, a proper care needs to be taken such that foreign matters caused by aerosol fine particles are not deposited inside the treatment chamber 1. For example, a driving recipe for cleaning inside the treatment chamber 1 is prepared in advance, and this recipe is periodically performed.

The chemical liquid 44 is a liquid which is a raw material for an organic etching gas. Vapor from the chemical liquid 44 is pumped into the treatment chamber 1 while being controlled by a mass flow controller 50-5 such that a desired flow rate and speed are achieved. While the vapor from the chemical liquid 44 is not being introduced into the treatment chamber 1, a valve 53 and a valve 54 are closed, and the tank 45 is shut off from the treatment chamber 1. A pipe for supplying vapor from the chemical liquid 44 is, if necessary, heated or kept warm such that the vapor from the chemical liquid 44 does not condense on the inner-wall surface thereof, and a purge gas is caused to circulate therein if necessary.

It may be preferable to detect an indication that the vapor will condense, by appropriately monitoring the temperature and pressure of in the pipes from the mass flow controller 50-5 to the treatment chamber 1, and to adjust a heating condition if necessary. In addition, in order to avoid pipe corrosion which is caused when molecules in organic vapor gas from the chemical liquid 44 are adsorbed or stored on the inner-wall surface of pipes that supply vapor from the chemical liquid 44, a gas purge mechanism (not illustrated) for forcing out residual gas and a mechanism (not illustrates) for maintain a vacuum within the pipes after the gas purge are also provided. In the gas purge mechanism, after the supplying of vapor from the chemical liquid 44 into the treatment chamber 1 from the mass flow controller 50-5 has ended, the residual gas is forced out by circulating an inert gas such as Ar or vapor from, for example, a solvent that can break down the chemical liquid 44, within pipes for supplying the vapor from the chemical liquid 44. By virtue of these mechanisms (the gas purge mechanism and the vacuum mechanism), even if, hypothetically, the vapor from the chemical liquid 44 condenses within the pipe, it is possible to minimize adverse effects at a time of treatment of the next wafer.

Note that a case of using the chemical liquid 44 has been described above. However, as the liquid raw material, a liquefied raw material resulting from melting and liquefying a solid or resulting from dissolving and liquefying a solid in, for example, a solvent may be used instead of a liquid at room temperature. In a case of a liquefied raw material obtained by melting and liquefying a solid, very-fine particles are achieved by using an atomizer, so that vaporization can easily be performed. Also, a high-concentration vapor is easily used. In addition, in a case of a liquefied raw material formed by dissolution and liquefaction in, for example, a solvent, pressure after vaporization is the sum of the vapor pressure of the raw material and the vapor pressure of the solvent. By using this property, the supply concentration of an active component in the treatment gas is easily adjusted.

A vacuum exhaust pipe 16 for decompressing the treatment chamber is provided under the treatment chamber 1. The vacuum exhaust pipe 16 is connected to a pump 15. The pump 15 includes, for example, a turbomolecular pump, a mechanical booster pump, or a dry pump, or a combination of these. In addition, a pressure-adjustment mechanism 14 increases or decreases a flow path cross-sectional area of the vacuum exhaust pipe 16 to thereby adjust a flow rate of, for example, gas discharged from within the treatment chamber 1. The pressure-adjustment mechanism 14 includes, for example, a plurality of plate-shaped flaps that are each disposed having an axis in a direction crossing the flow path and that rotate around the axis, and a plate member that moves inside of the flow path by crossing the axial direction.

An IR (Infra-red) lamp unit for heating the wafer 2 is installed between the stage 4 and the quartz chamber 12. The IR lamp unit includes an IR lamp 62 disposed in a ring shape above the stage 4, a reflective plate 63 disposed to cover the IR lamp 62 in order to reflect light emitted from the IR lamp 62 downward, and an IR-light-transmissive window 74.

The IR lamp 62 according to the present embodiment includes multiple circular lamps that are horizontally disposed concentrically or helically around a central axis of the base chamber 11 or the cylindrical stage 4 in an up-down direction. The disposition of the IR lamp 62 is not limited to this as long as it is possible to perform wafer heating which is described below. In the present embodiment, light having a wavelength band ranging from visible light to an infrared region is used, and this light is referred to as IR light. In the configuration illustrated in FIG. 1, as the IR lamp 62, IR lamps 62-1, 62-2, and 62-3 are installed around the quartz chamber 12 at portions corresponding to three circumferences. The IR lamp 62 is not limited to three circumferences and may be two or four circumferences, for example.

An IR lamp power supply 64 is connected to the IR lamp 62. The IR lamp power supply 64 has a function of independently controlling power to be supplied to the IR lamps 62-1, 62-2, and 62-3, and adjusts an amount of heat when the wafer 2 is being heated.

A gas flow path 75 is disposed to be surrounded by the IR lamp unit. The treatment gas, for which supplying is controlled by the mass flow controller 50 (50-1 through 50-3, and 50-5), flows from the quartz chamber 12 to the treatment chamber 1 through the gas flow path 75. A slit plate (ion-blocking plate) 78 in which a plurality of through holes are provided and which is for blocking ions or electrons from among components of plasma generated in the quartz chamber 12 and for transmitting only neutral gas or neutral radicals is disposed in the gas flow path 75. In a case of not using plasma, the treatment gas is a neutral gas that does not include ions or electrons, and thus, the slit plate 78 functions as a straightening vane for straightening the flow of the treatment gas.

In addition, the dimensions or arrangement of the through holes are optimized such that the treatment gas is appropriately preheated when the treatment gas passes through the through holes in the slit plate 78. Moreover, the installation location of the slit plate 78 is set in consideration of the positions of the IR lamp units, such that it is possible to exercise preheating functionality.

A flow path 39 for a coolant for cooling the stage 4 is formed inside the stage 4. A chiller 38 supplies the coolant, and causes the coolant to circulate within the flow path 39. In addition, electrostatic chucking electrodes 30 for electrostatic chucking the wafer 2 are embedded in the stage 4, and electrostatic chucking power supplies 31 are connected to the electrostatic chucking electrodes 30.

In addition, in order to improve efficiency of cooling the wafer 2, He gas is supplied between the back surface of the wafer 2 placed on the stage 4 and the stage 4. The He gas is introduced from an opening in the top surface of the stage 4 to a gap between the back surface of the wafer 2 and the top surface of the stage 4, through a supply pipe provided inside and on the top surface of the stage 4.

In a case of heating or cooling the wafer 2 in a state where the wafer 2 is chucked, there is a risk that the back surface of the wafer 2 is scratched due to a difference in coefficients of thermal expansion between the wafer 2 and the stage 4. Therefore, a corrosion-resistant coating made of resin is applied onto at least a wafer mounting surface of the stage 4, and the occurrence of scratches on the back surface of the wafer 2 is prevented. Note that the coating applied to the wafer mounting surface of the stage 4 has a function of also preventing the stage 4 from being affected by, for example, a treatment gas or plasma or radicals thereof.

In addition, a thermocouple 70 for measuring the temperature of the stage 4 is installed inside the stage 4. The thermocouple 70 is connected to a thermocouple thermometer 71.

As other means for measuring the temperature of the wafer 2, optical fibers 92-1 and 92-2 may be installed at three locations, that is, near the center of the stage 4, near the middle of the stage 4 in the radial direction, and near the outer periphery of the stage 4 in the radial direction. The optical fibers 92-1 are provided to pass through the inside of the stage 4, and guide external IR light outputted from an external IR light source 93 to the back surface of the wafer 2, thereby applying the light to the back surface of the wafer 2.

In contrast, the optical fibers 92-2 collect IR light that is applied through the optical fibers 92-1 and that penetrates and is reflected by the wafer 2, and transmit this IR light to a spectrometer 96. The external IR light generated by the external IR light source 93 is split into a plurality of optical paths (FIG. 1 illustrates a configuration example in which the light is split into three optical paths) after going through an optical path switch 94 and an optical distributor 95, and the split light beams are then applied onto respective positions on the back surface of the wafer 2 via the optical fibers 92-1 corresponding to optical paths for different circuits.

IR light absorbed or reflected by the wafer 2 is captured by the optical fibers 92-2 and transmitted to the spectrometer 96. A detector 97 detects spectral intensity distribution (optical spectrum) data for each wavelength band. The optical spectrum data is sent to a calculation section 41 of a control unit 40, and is used to obtain the temperature of the wafer 2 after predetermined calculation. In addition, regarding light subjected to spectroscopic measurement, it is possible to obtain the temperature of respective locations according to a mechanism for switching measurement points on a wafer where the spectroscopic measurement of light is performed.

Note that, needless to say, optical fibers used here are soundly sealed by using, for example, packing so as not to be affected by, for example, the treatment gas fed through the mass flow controllers 50-1, 50-2, 50-3, and 50-5, or plasma or radicals thereof. However, in order to prevent measurement performance from decreasing immediately after a seal leaks due to the deterioration of, for example, packing for a sealing part which is caused by the continuous use of the semiconductor manufacturing apparatus according to the invention of the present application, it is desirable to use an optical fiber material having material properties that are less likely to react with, for example, the fed treatment gas or plasma or radicals thereof. For example, in a case where the treatment gas fed from the mass flow controller 50-5 includes F atoms, it may be desirable to use, for example, a hollow fiber instead of a quartz fiber.

The control unit 40 controls on (output is present) and off (no output) of the supply of high-frequency power from the high-frequency power supply 20 to the ICP coil 34. In addition, the control unit 40 controls the integrated mass flow controller control unit 51 or the organic gas vaporizer supply device 47 such that a gas is fed into the quartz chamber 12 according to a timing defined by a desired time chart (details thereof are described below). The control unit 40 also controls the vacuum exhaust pipe 16 and the pump 15 to perform adjustment such that inside the treatment chamber 1 enters a desired pressure range.

The control unit 40 also performs control for chucking the wafer 2 onto the stage 4, and for performing heating and cooling such that the wafer 2 has a desired temperature and temperature distribution. Specifically, on the basis of temperature information regarding the wafer 2 that is outputted from the thermocouple thermometer 71 and temperature information regarding the wafer 2 that is calculated from an optical spectrum outputted from the detector 97, a voltage applied to the electrostatic chucking power supplies 31 is adjusted, a flow rate of He gas is adjusted under the control of the mass flow controller 50-4, and the IR lamp power supply 64 and the chiller 38 are controlled, whereby the temperature and temperature distribution of the wafer 2 are maintained within predetermined ranges.

### (Wafer Treatment)

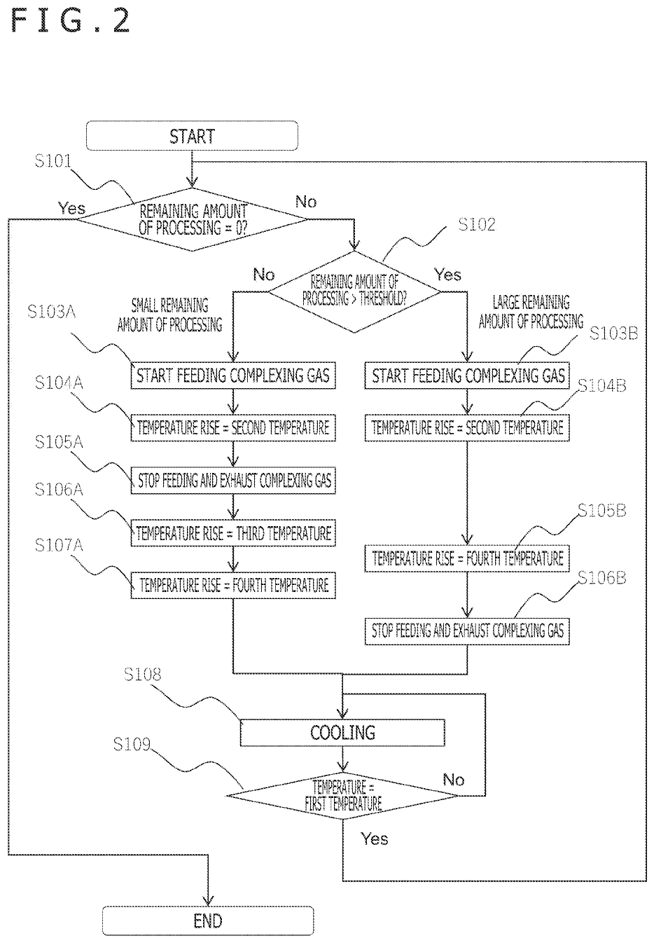

Next, with reference to FIG. 2, a wafer treatment performed in the semiconductor manufacturing apparatus according to the present embodiment will be described. FIG. 2 is a flow chart that illustrates the wafer treatment performed in the semiconductor manufacturing apparatus. Here, a film to be treated by the wafer treatment (hereinafter, will also be referred to as a “film to be treated” or a “to-be-treated film”) is formed in advance on the wafer 2. The film to be treated includes a typical metal element such as Al₂O₃, and etching of this film will be described. Note that a “typical metal element” means a main-group element not including a non-metallic element such as C or a Si metalloid element. In addition, the treatment in the flow chart is controlled by the control unit 40.

### <Preparatory Stage for Wafer Treatment>

Before each step illustrated in FIG. 2, the wafer 2 is conveyed by, for example, a conveying robot arm. The wafer 2 passes through a wafer loading/unloading port provided in the base chamber 11, is introduced into the treatment chamber 1, and is placed on the stage 4.

The wafer 2 placed on the stage 4 is chucked by the electrostatic chucking mechanism provided inside the stage 4, to be chucked onto the stage 4. A laminated film structure that includes the film to be treated, which has been processed into a pattern shape for forming the structure of a circuit for a semiconductor device, is formed in advance on the top surface of the wafer 2.

The film to be treated according to the present embodiment is aluminum oxide (Al₂O₃), but the technique according to the present embodiment can also be applied to films of other types of materials. For example, the film is not limited to a film that includes a typical metal element as with Al₂O₃, and the present embodiment is applicable to a film that includes a transition metal element. A film structure that includes the film to be treated is fabricated to have such a film thickness that enables the formation of a desired circuit, by using a publicly-known sputtering method, a PVD (Physical Vapor Deposition) method, an ALD (Atomic Layer Deposition) method, a CVD (Chemical Vapor Deposition), or the like. In addition, the film may be processed by using a photolithography technique to have a shape corresponding to a circuit pattern.

In addition, the control unit 40 adjusts the temperature of the wafer 2. In the present embodiment, when it is determined that the temperature of the wafer 2 has reached a first temperature (details are described below), the etching treatment with respect to the film to be treated on the wafer 2 is started.

### <Wafer Treatment in Flow Chart>

A first step S101 is a step of determining a remaining film thickness, which should be etched, of the film to be treated that is formed on the wafer 2. In this step, while design or specification values for a semiconductor device to be manufactured by using the wafer 2 are referred to as appropriate, the remaining film thickness (hereinafter, will also be referred to as a “remaining amount of processing”) of the film to be treated is determined by the control unit 40. This step is performed both in a case where the etching treatment is performed for the first time on the film to be treated after the wafer 2 has been carried in and a case where the etching treatment has already been performed. The calculation section 41 of the control unit 40 reads out software stored in a storage device disposed internally, and performs a calculation according to an algorithm written in the software. The control unit 40 calculates a value for an amount of cumulative processing (hereinafter, also referred to as a “cumulative processing amount”) based on the treatment that is performed on the wafer 2 before the wafer 2 is carried into the treatment chamber 1, and a cumulative processing amount based on the treatment that is performed after the wafer 2 has been carried into the treatment chamber 1, and determines whether or not additional processing according to the technique of the invention of the present application is necessary, on the basis of design and specification values for the semiconductor device to be manufactured by using the wafer 2. In addition, in the present embodiment, an amount of processing is determined in units of physisorption layers. Strictly speaking, the length of time required for several physisorption layers to be coated depends on, for example, the shape of a sample to be processed or a processing stage and is thus desirably set by causing a value determined on the basis of a prior experiment to have a safety margin.

Note that a cumulative processing amount which corresponds to an amount obtained when the treatment illustrated in FIG. 2 is performed at least once can simply be determined from the cumulative number of treatment cycles for one group of step S103 through step S109 and an amount of processing (cycle processing rate) for one treatment cycle, which is obtained in advance. A value for a cumulative processing amount obtained in this manner is purely a value that is estimated simply. Thus, the value may be determined from surface analysis of the sample, an output result from a film thickness monitoring apparatus (not illustrated), various process monitoring measurement results such as a result of a processing shape or surface roughness, or a combination of these, and, if necessary, is desirably revised or corrected in combination with a simplified estimated cumulative amount of processing from the cycle processing rate.

In step S101, in a case where it is determined that the remaining amount of processing is 0 or where a tolerance value 80 to be regarded as 0 is set and it is determined that a remaining processing value is smaller than the tolerance value 80, the treatment with respect to the film to be treated ends. If necessary, for example, an etching treatment using a plasma, such as RIE (Reactive-ion Etching) using an ICP plasma, may be performed.

In a case where it is determined that the remaining amount of processing is not 0 (or is equal to or greater than 80), the process proceeds to the next step S102. In step S102, the remaining amount of processing for the film to be treated that is formed on the wafer 2 is compared with a predetermined threshold. The process proceeds to step S103B in a case where the remaining amount is determined to be greater than the threshold, but proceeds to step S103A in a case where the remaining amount is determined to be equal to or less than the threshold. In the following description, step S103B to step S106B are referred to as steps B, and step 103A to step S107A are referred to as steps A.

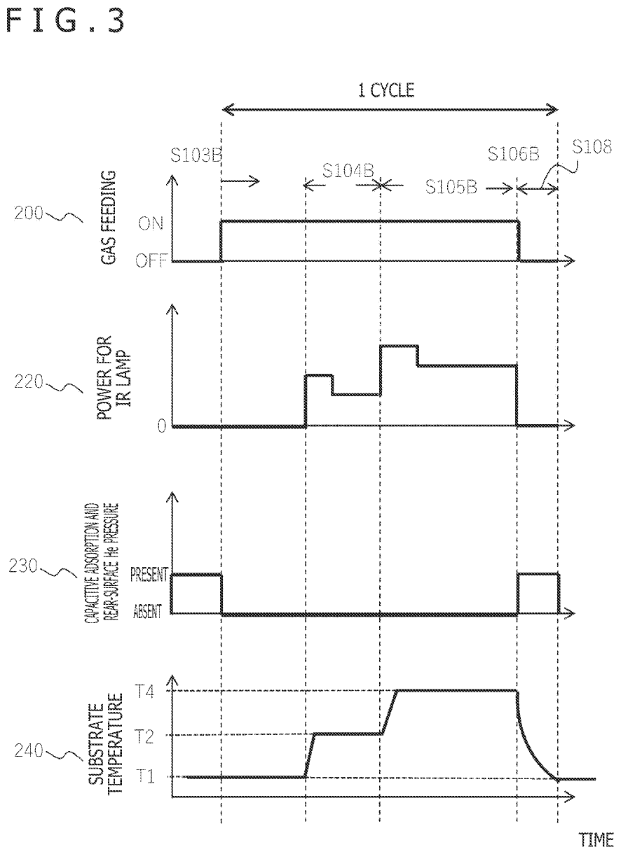

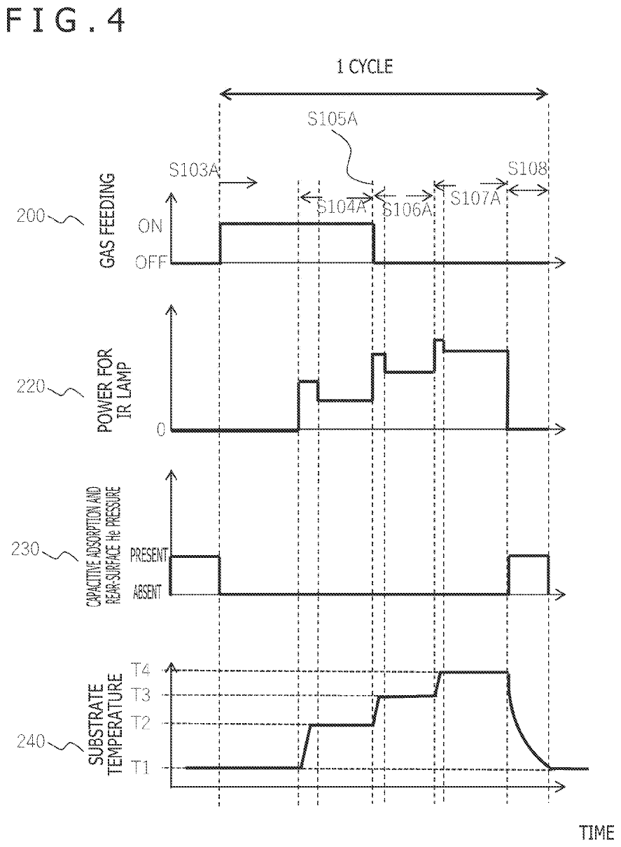

Next, also referring to FIG. 3 and FIG. 4, the wafer treatment performed in a semiconductor manufacturing apparatus 100 according to the present embodiment will be described.

### (Steps B)

FIG. 3 illustrates a time chart for the steps B that include step S103B through step S106B. FIG. 4 illustrates a time chart for the steps A that include step S103A through step S107A. Note that FIGS. 3 and 4 schematically illustrate the temperature of the wafer 2 and operations for supplying and exhausting a gas during the etching treatment of the wafer 2 in the present embodiment. A temperature, a temperature gradient, or a control time period illustrated in FIGS. 3 and 4 are appropriately selected by considering, for example, a material to be etched, a type (composition) of treatment gas, and the structure of the semiconductor device.

As illustrated in a chart 230 of FIG. 3, electrostatic chucking is first performed with respect to the wafer 2, and He gas is introduced to the back surface of the wafer 2. In this manner, the temperature of the wafer 2 is maintained at a first temperature T1, as illustrated in a chart 240.

In step S103B in FIG. 2, supplying of vapor from the chemical liquid 44 stored in the tank 45 is started by the mass flow controller 50-5, as illustrated in a chart 200 in FIG. 3. The vapor from the chemical liquid 44 has a component for converting the film to be treated on the wafer 2, which is placed inside the treatment chamber 1, to an organometallic complex having volatility, and is an organic gas for the etching treatment.

This organic gas is for reacting with the film to be treated, to cause an organometallic complex to be formed, and may thus be referred to below as a complexing gas for simplicity in the present disclosure. In the present embodiment, conditions for supplying the complexing gas (such as supply amount, supplying pressure, length of time for supplying, and gas temperature) or a type of complexing gas are determined in consideration of the elemental composition, shape, and film thickness of the film to be treated within the semiconductor device, as well as the film composition within the device. The mass flow controller 50-5 is controlled on the basis of a control signal from the control unit 40.

In step S103B in FIG. 2, a physisorption layer for complexing gas molecules is formed on the surface of the film to be treated that is formed on the wafer 2. The control unit 40 determines that a requisite minimum number of physisorption layers have been formed in step S103B. This step is performed while the temperature of the wafer 2 is maintained in a temperature range equal to or less than the boiling point of the complexing gas. As illustrated in the chart 240 of FIG. 3, the wafer 2 is set to a first temperature T1, and the first temperature T1 is in a temperature range set on the basis of the boiling point of the complexing gas. Note that, as illustrated in the chart 230, electrostatic chucking is not performed with respect to the wafer 2, and supplying of He gas is also stopped.

After a predetermined complexing gas is fed in step S103B in FIG. 2, the process proceeds to step S104B, and the temperature of the wafer 2 is raised to a second temperature T2. In step S104B, while an organic gas including a material having, within a molecule thereof, at least two substituents which hold a lone pair is fed, the wafer 2 is heated, whereby a compound made from the film to be treated and the organic gas is formed. In this step, in a state where supply of the complexing gas is being continued, power is supplied from the IR lamp power supply 64 to the IR lamp 62 to emit IR light, and the wafer 2 is irradiated with the IR light. As illustrated in a chart 220 of FIG. 3, the power for the IR lamp 62 is raised for only a predetermined period of time and is then reduced. After that, the power is controlled to be kept constant. With the IR light applied, the wafer 2 is heated, and the temperature thereof is quickly raised to the second temperature T2 as illustrated in the chart 240. The wafer 2 is heated, and the temperature thereof is raised to the predetermined second temperature T2 higher than the first temperature T1 and maintained at that temperature, whereby reactions at the surface of the film to be treated are activated. Also, an adsorption state of molecules of the complexing gas being physically adsorbed on the film surface changes from a physisorption state to a chemisorption state.

Further, in the following step S105B, the temperature of the wafer 2 is raised to a fourth temperature T4. In this step, in a state where supplying of the complexing gas into the treatment chamber 1 is continuing, the wafer 2 is heated with the IR light applied from the IR lamp 62, and the temperature of the wafer 2 is raised to the fourth temperature T4 which is higher than the second temperature T2, as illustrated in the chart 240 of FIG. 3. As illustrated in the chart 220, the power for the IR lamp is raised for only a predetermined period of time and is then reduced. After that, the power is controlled to be kept constant. With the IR light applied, the wafer 2 is heated, and the temperature thereof is quickly raised to the fourth temperature as illustrated in the chart 240. When the temperature of the wafer 2 is raised to the fourth temperature T4 and maintained at this temperature, the following phenomena happen in parallel: (1) a first phenomenon in which an organometallic complex generated on the surface of the film to be treated volatilizes to desorb and be removed from the surface of this film; and (2) a second phenomenon in which the complexing gas which is continuously fed reacts with the surface of the film to be treated, forming the organometallic complex. Regarding step S105B, when a specific small region on the surface of the film to be treated is viewed microscopically, the removal by volatilization (desorption) of the complex on the film surface and the formation of a new complex proceeds intermittently or in a stepwise manner in the order of (1), (2), (1), and (2) on the film surface in this region. In a case where the surface of the film to be treated is viewed as a whole, it can essentially be understood that continuous etching is proceeding.

Then, the process proceeds to step S106B in FIG. 2. The supplying of the complexing gas is stopped, and the gas inside the treatment chamber 1 is exhausted. In step S106B, on the basis of a result of the comparison in step S102, after step S104B, the wafer 2 is further heated to raise the temperature thereof to a predetermined temperature and cause the organometallic complex to desorb from the surface of the wafer 2. In step S106B, the wafer 2 continues to be heated while the organic gas is supplied, raising the temperature of the wafer 2 to the predetermined temperature. As illustrated in the chart 200 of FIG. 3, the supply of the complexing gas is stopped. While the above-described step S101 through step S105B and step S106B are performed, the pump 15 is continuously driven. The gas in the treatment chamber 1 is continuously exhausted via the vacuum exhaust pipe 16 which connects the pump 15 with the treatment chamber 1.

Because the supplying of the complexing gas is stopped in step S106B, a gas including the organometallic complex which is volatilized from the film to be treated is entirely exhausted from the treatment chamber 1. At this time, an unreacted complexing gas staying within a pipe for supplying the complexing gas, specifically, the pipe from the mass flow controller 50-5 to the treatment chamber 1, is also discharged by the vacuum exhaust pipe 16 and the pump 15 via the treatment chamber 1. In addition, in steps performed after S106B, exhausting is continuously performed.

### (Steps A)

In contrast, in step S103A in FIG. 2, the supplying of the complexing gas is started as illustrated in a chart 200 of FIG. 4. After a requisite minimum number of physisorption layers have been formed in the control unit 40 in step S103A, the process proceeds to step S104A. IR light emitted from the IR lamp 62 is applied to the wafer 2, thereby heating the wafer 2, and the temperature of the wafer 2 is raised to the second temperature T2 as illustrated in a chart 240 of FIG. 4. As illustrated in the chart 220 of FIG. 4, the power for the IR lamp is increased for only a predetermined period of time and is then reduced. After that, the power is controlled to be kept constant.

As in the case of the step 103B in the steps B, conditions for supplying the complexing gas (such as supply amount, supplying pressure, length of time for supplying, and temperature) or the type (composition) of complexing gas are determined in consideration of the elemental composition, shape, and film thickness of the film to be treated within the semiconductor device, as well as the film composition within the device. In addition, in step S104A, as in the case of step S104B, the temperature of the wafer 2 is raised to the second temperature T2 and is then maintained at that temperature, whereby reactions at the surface of the film to be treated are activated. Also, an adsorption state of molecules of the complexing gas being physically adsorbed on the film surface changes from a physisorption state to a chemisorption state. In step S104A, while an organic gas including a material having, within a molecule thereof, at least two substituents which hold a lone pair is fed, the wafer 2 is heated, whereby a compound made from the film to be treated and the organic gas is formed.

The complexing gas is chemisorbed on the surface of the film to be treated in the treatment of step S104A. In such a state, there are chemical bonds between the molecules of the complexing gas and metal atoms included in the film to be treated, e.g., Al atoms in a case where the film to be treated is an Al₂O₃ film, and they are strongly bonded to each other. In other words, the molecules of the complexing gas can be said to be “pinned” to the surface of the film to be treated.

As a result, a diffusion rate at which the molecules of the complexing gas diffuse from the surface of the film to be treated is slow. The speed at which complexing gas molecules diffuse into the film to be treated via the chemisorption layer formed on the surface of the film to be treated is particularly slow. With a leveling (surface homogenization) effect produced when the diffusion into the film is slow, surface unevenness on the film to be treated is smoothed during the steps from S103A to S107A. Note that a state in which complexing gas molecules are pinned is considered to be occurring also in step S104B.

In the subsequent step S105A, the supplying of the complexing gas is stopped, and the gas inside the treatment chamber 1 is exhausted. By exhausting the gas inside the treatment chamber 1, the complexing gas being chemisorbed on the surface of the film to be treated is retained, whereas the complexing gas in an unadsorbed state or in a physisorption state is entirely exhausted from the treatment chamber 1. In addition, an unreacted complexing gas staying within a pipe for supplying the complexing gas, specifically, the pipe from the mass flow controller 50-5 to the treatment chamber 1, is also discharged via the treatment chamber 1 by the vacuum exhaust pipe 16, the pump 15, and the gas purge mechanism and the vacuum mechanism that are attached to the pipe.

In the following step S106A, the temperature of the wafer 2 is increased to the third temperature T3. In step S106A and later-described S107A, on the basis of a result of the comparison in step S102, after step S104A, the wafer 2 is further heated to raise the temperature thereof to a predetermined temperature and cause the organometallic complex to desorb from the surface of the wafer 2. In step S106A and step S107A, the supplying of the organic gas is stopped, and the wafer 2 is then heated in a plurality of stages to raise the temperature thereof to a predetermined temperature. According to a command signal from the control unit 40, the application intensity of the IR light which has continuously been applied from the IR lamp 62 since step S104A is increased to raise the temperature of the wafer 2 to the third temperature T3. As illustrated in the chart 220 of FIG. 4, the power for the IR lamp is increased for only a predetermined period of time and is then reduced. After that, the power is controlled to be kept constant. With the IR light applied, the wafer 2 is heated, and the temperature thereof is quickly raised to the third temperature T3 as illustrated in the chart 240. In this step, the temperature of the wafer 2 is raised to the third temperature T3 and is then maintained at this temperature, whereby complexing gas molecules being chemisorbed on the surface of the film to be treated are gradually converted to a volatile organometallic complex by a complexation reaction with the film to be treated at the film surface. In this step, the supply of the complexing gas is stopped as illustrated in the chart 200 of FIG. 4. As described above, complexing gases are not present within the treatment chamber 1 except the complexing gas being fixed by chemisorption to the surface of the film to be treated. The amount of organometallic complex layer generated is substantially regulated by the amount of the chemisorption layer, and the thickness of the organometallic complex layer is equal to or less than the thickness of the chemisorption layer.

In the following step S107A, the temperature of the wafer 2 is raised to the fourth temperature T4. The application intensity of the IR light which has been continuously emitted from the IR lamp 62 is further increased to raise the temperature of the wafer 2 to the fourth temperature T4, and the temperature of the wafer 2 is maintained at the fourth temperature T4. As illustrated in the chart 220 of FIG. 4, the power for the IR lamp is increased for only a predetermined period of time and is then reduced. After that, the power is controlled to be kept constant. With the IR light applied, the wafer 2 is heated, and the temperature thereof is quickly raised to the fourth temperature T4 as illustrated in the chart 240. In this step, a temperature at which the organometallic complex formed in the previous step S106A volatilizes and desorbs is maintained, and the organometallic complex is removed from the surface of the film to be treated.

### (Action of Steps A and Steps B)

The steps A including the series of steps: step S103A, step S104A, step S105A, step S106A, and step S107A, and the steps B including a series of steps: step S103B, step S104B, step S105B, and step S106B are the same in that the temperature of the wafer 2 is raised to the second temperature T2 and that a chemisorption layer is generated on the surface of a film including a transition metal. However, the steps A and the steps B are different after the step in which the chemisorption layer is converted to an organometallic complex.

In other words, as illustrated in the steps A, when the temperature of an organometallic complex or a film having the organometallic complex on the surface thereof is raised to the fourth temperature T4 at which the organometallic complex is volatilized and removed in a state where the supplying of the complexing gas is stopped, volatilization and removal of approximately one to several layers of the organometallic complex that have been converted from a chemisorption layer end, and the reaction ceases at a time when the film to be treated that is placed directly below the removed layers is exposed within the treatment chamber 1. In contrast, as illustrated in the steps B, when the temperature is raised to the fourth temperature T4 at which the organometallic complex is volatilized and removed while the supplying of the complexing gas is continued, volatilization and removal of approximately one to several layers of the organometallic complex that have been converted from a chemisorption layer end, and the unreacted film to be treated that is placed directly below the removed layers is exposed. At this time, the exposed film to be treated is heated to the fourth temperature T4, whereby reactivity increases, and thus, the exposed film is directly converted to the organometallic complex when coming into contact with the complexing gas. Further, the generated organometallic complex is quickly volatilized and removed, and as a whole continuous etching of the film to be treated advances.

In the steps B, there is a reaction in which the film to be treated is directly converted to an organometallic complex and is further volatilized and removed, and thus, there is exhibited a phenomenon in which a minute highly-chemically-active region that is present on the surface of the film to be treated, such as a region having a grain boundary or a specific crystal orientation, is preferentially converted to the organometallic complex and removed. In addition, there is a self-assembling planar orientation growth process when the chemisorption layer is generated. In the steps B, however, the organometallic complex layer is directly generated without going through this self-assembling planar orientation growth process, and thus, this organometallic complex layer more or less does not have the orientation. As a result, the surface of the treated film to be treated that has undergone the treatment is not planarize, but has more unevenness and is roughened.

In contrast, in the steps A, by the action of the self-assembling orientation made when a chemisorption layer is formed and the action of the diffusion rate of the complexing gas molecules being suppressed within the chemisorption layer that has undergone oriented growth having the self-assembling orientation, planarization of the surface of the film to be treated, such as an Al₂O₃ film, proceeds.

Note that, after a prior evaluation is made before the wafer 2 is treated, the fourth temperature T4 is set to be lower than the temperature at which the complexing gas molecules start decomposing or the temperature at which the organometallic complex molecules start decomposing, and to be higher than the temperature at which the organometallic complex molecules start volatilizing. In addition, in a case where the difference between the temperature at which the organometallic complex molecules start decomposing and the temperature at which the organometallic complex molecules start volatilizing is small and insufficient in the light of the specification of the semiconductor manufacturing apparatus 100, such as a characteristic of the uniformity of temperature in the planar direction of the top surface of the stage 4, an existing method for reducing the temperature at which the organometallic complex molecules start volatilizing, such as a method for reducing the pressure within the treatment chamber 1 in order to widen a mean free path, may be applied.

In a case where, by the prior evaluation, it is determined that the temperature at which the organometallic complex molecules start decomposing is lower than the temperature at which the organometallic complex molecules start volatilizing, the combination of the material properties of the film to be processed and the organic gas molecules for etching is inappropriate, and thus, another material is selected from among candidate material for the organic gas for etching, which are described below. Note that it is possible to actively use a mismatch in a combination of material for the film to be processed and the organic gas molecules for etching, to selectively etch only a layer of a specific material in a multilayer structure.

(Steps after the Steps A and the Steps B)

Next, common steps that are performed after the steps A and the steps B will be described. The process proceeds to step S108, and cooling of the wafer 2 is started. As illustrated in the charts 220 of FIG. 3 and FIG. 4, the supply of electrical power to the IR lamp is stopped. Before S108 starts, a treatment for definitely exhausting the complexing gas is performed. As illustrated in charts 200 of FIG. 3 and FIG. 4, before S108 starts, the supplying of the complexing gas should already be stopped, and exhausting of an unreacted complexing gas remaining or being retained within the pipe for supplying the complexing gas, specifically, the pipe from the mass flow controller 50-5 to the treatment chamber 1, should already be finished. However, in a case where some kind of trouble or an unexpected event happens and the complexing gas remains somewhere, there is a risk that the remaining complexing gas will be a cause of foreign matters being generated. Therefore, in the present embodiment, the operation of discharging the complexing gas via the treatment chamber 1 by the vacuum exhaust pipe 16 and the pump 15 is performed again.

In addition, in order to remove the complexing gas that is adsorbed or stored on an inner wall of a pipe, before the process proceeds to the cooling step S108, what is called a purge operation is also performed. In the purge operation, the inside of the pipe from the mass flow controller 50-5 to the treatment chamber 1 is filled with an inert gas, and the gas is then exhausted. In order to reliably exhaust the gas that remains or is retained within pipes from the mass flow controllers 50-1, 50-2, 50-3, 50-4, and 50-5 to the treatment chamber 1, a waste gas path (not illustrated) may be provided, if necessary.

In the case of the flow for either of the steps A and B, the process proceeds to step S108, and cooling of the wafer 2 is started. The cooling of the wafer 2 is continued until it is detected in step S109 that the temperature of the wafer 2 has reached a predetermined first temperature. As illustrated in the charts 230 of FIG. 3 and FIG. 4, electrostatic chucking is performed with respect to the wafer 2, and He gas is introduced to the back surface of the wafer 2. It is desirable for the cooling gas to be fed between the stage 4 and the wafer 2 in the substrate cooling step S108. For example, He, Ar, or the like is suitable as the cooling gas. When He gas is fed, cooling in a short length of time is possible, so that processing productivity increases. Note that, as described above, the flow path 39 which is connected to the chiller 38 is provided inside the stage 4, and thus, the wafer 2 is gradually cooled when the wafer 2 is merely electrostatically chucked onto the stage 4, even in a state in which a cooling gas such as He does not flow.

As described above, the thermocouple 70 for measuring the temperature of the stage 4, optical fibers 92 for detecting the temperature of the wafer, or the like are disposed at a plurality of locations inside the stage 4, and are connected to corresponding ones of the thermocouple thermometer 71, the detector 97, and the like. It is possible to employ, instead of them, any other temperature measuring means as long as it can appropriately measure the temperature of the wafer 2 or the wafer stage 4. On the basis of signals obtained by such temperature measuring means, the control unit 40 detects that the stage 4 has reached a predefined predetermined temperature such as the first temperature T1 as illustrated in the charts 240 of FIG. 3 and FIG. 4. Then, one cycle of the treatment for etching the film to be treated on the wafer 2 ends.

After the control unit 40 determines that the temperature of the wafer 2 has reached the first temperature T1 and a first cycle of the treatment has ended, the process returns to step S101, and it is determined whether or not the remaining amount of processing has reached 0. As described above, when the control unit 40 determines that the remaining amount of processing has reached 0, the etching treatment of the film to be treated on the wafer 2 is ended. On the other hand, in the case where it is determined that the remaining amount of processing is greater than 0, the process proceeds to step S102 again, and either the steps A or the steps B are performed.

Specifically, in a case where the determination result is “large remaining amount of processing,” as described above, the steps are performed in the order of steps S103B through S106B, S108, and S109. In contrast, in a case where the determination result of S102 is “small remaining amount of processing,” the steps are performed in the order of steps S103A through S107A, S108, and S109.

In the case where the treatment of the wafer 2 ends, the supplying of He gas for cooling is stopped. Further, the following steps are also performed: a step of discharging He gas from the back surface of the wafer 2 by opening a valve 52 which has been closed, the valve 52 being disposed on the waste gas path that connects a He gas supply path with the vacuum exhaust pipe 16; and a step of canceling electrostatic chucking of the wafer 2.

Then, the treated wafer 2 is handed over to a conveyance robot through the wafer loading/unloading port in the base chamber 11, and an untreated wafer 2 that is to be treated next is carried in. Needless to say, in a case where there is no untreated wafer 2 to be treated next, a wafer loading/unloading gate is blocked, and the operation for manufacturing a semiconductor device by the semiconductor manufacturing apparatus 100 stops.

Note that, in the present embodiment, the second temperature T2, the third temperature T3, and the fourth temperature T4, which are set in each of the steps A and the steps B described above, do not necessarily need to have the same values across the steps A and the steps B. The temperatures are carefully examined before the wafer 2 is treated, and an appropriate temperature range can be set. The control unit 40 sets temperatures for the respective steps A and B according to specifications of the film to be treated on the wafer 2.

### First Example

Next, a specific example of the semiconductor manufacturing method performed in the semiconductor manufacturing apparatus according to the present embodiment will be described.

In the present example, as a stage prior to the start of the etching treatment of the wafer 2, the wafer 2 is conveyed and held by being chucked onto the stage 4 within the treatment chamber 1. A film to be treated, such as an Al₂O₃ film surface, that includes a typical metal element and that has been processed into a desired pattern shape is deposited in advance onto the surface of the wafer 2, and part of the film is being exposed.

After the wafer 2 is held by being electrostatically chucked onto the stage 4, the pressure inside the treatment chamber 1 is reduced, and the wafer 2 is heated. When the wafer 2 is heated and the temperature thereof is raised, a gas (such as water vapor) or a foreign matter adsorbed on the surface of the wafer 2 is caused to desorb.

When it is confirmed that gas components adhering to the surface of the wafer 2 have sufficiently desorbed, while the state in which the inside of the treatment chamber 1 is reduced in pressure is maintained, heating of the wafer 2 is stopped, and cooling of the wafer 2 is started. It is possible to use publicly-known means to cool or heat the wafer 2 in this step. For example, heat conduction by a heater disposed inside the stage 4 or radiation of light radiated from a lamp is used to heat the wafer 2.

Besides such heating, a foreign matter adhering to the wafer 2 may be removed by using, for example, cleaning or ashing of the surface using a plasma formed within the treatment chamber 1. Note that, in a case where it is reliably confirmed that the surface of the wafer 2 is sufficiently clean and has no matter attached, adsorbed, or otherwise thereon, for example, a wafer heating step may be omitted, but is desirably performed from the perspective of warming-up the treatment chamber 1, in particular, the inner walls of the treatment chamber 1.

When the control unit 40 determines that the temperature of the wafer 2 has dropped and reached the first temperature T1 which is predefined or a temperature equal to or less than the first temperature T1, the treatment of the wafer 2 is performed according to the flow chart illustrated in FIG. 2. Note that, before the treatment of the wafer 2 starts, for example, before the wafer 2 is carried into the treatment chamber 1, treatment conditions such as the pressure within the treatment chamber 1 and the type and flow rate of gas used when treating a film to be treated on the wafer 2, the treatment conditions being what is called a treatment recipe, are detected in the control unit 40. For example, an ID (Identification) number of each wafer 2 is obtained by reading, for example, a mark on the wafer 2, and data regarding the wafer 2 corresponding to the ID number is obtained by referring to data from a production management database through a facility for communication, such as a network, connected to the control unit 40. The data includes, for example, a treatment history, the composition, thickness, and shape of a film to be treated which is a target of the etching treatment, an amount of etching to be performed on the target film to be treated (a remaining film thickness set as a target and a depth to etch), and a condition for an end point of etching.

For example, assumed is a case in which the control unit 40 has detected that the treatment to be performed on the wafer 2 is an etching treatment for removing a 0.2 nm Al₂O₃ film which is smaller than a predetermined threshold (for example, 0.5 nm). In this case, because the ion radius of aluminum (3+) and the ion radius of oxygen (2−) are respectively approximately 0.5 Angstrom and approximately 1.3 Angstrom, it is determined that this is a treatment for removing approximately one atomic or molecular layer of Al₂O₃, and the “remaining amount of processing≤threshold” is determined in step S102 in FIG. 2. According to the flow for the steps A (S103A→S104A→S105A→S106A→S107A), signals are sent from the control unit 40 to various parts in the semiconductor manufacturing apparatus 100 to perform the treatment of the film. Note that an amount of the film to be treated that is etched every time one cycle of the steps A is performed is measured in advance, and the abovementioned predetermined threshold is set on the basis of a measurement value for an amount of the treatment in one cycle of the steps A.

In contrast, in a case where it is determined in the control unit 40 that it is a treatment for removing a thickness of 5 nm of Al₂O₃ films which exceeds the predetermined threshold (for example, 0.5 nm), for example, 10 or more and close to 20 Al₂O₃ layers must be removed. In a case of etching one layer at a time as described above, the treatment is repeated ten or more times. In such a case, the length of time required for the treatment becomes n times greater, and productivity is impaired. Accordingly, a treatment for firstly collectively removing a plurality of layers (for example, 7 or 8 layers or more than this), and subsequently removing remaining film layers one at a time is performed. In the present example, in this case, the film to be treated is treated at least once according to the flow in the steps B (S103B→S104B→S105B→S106B) following the step in which “remaining amount of processing >threshold” is determined in FIG. 2, and then, the flow in the steps A (S103A→S104A→S105A→S106A→S107A) is performed. Consequently, an Al₂O₃ film having a total thickness of 5 nm is removed by the flow in the steps B and the flow in the steps A. An amount of the film to be treated that is etched each time one cycle of the steps B is performed is measured in advance, and the number of repetitions of the steps B is set on the basis of an amount removed by etching and a measurement value for the amount of the treatment in a cycle of the steps B.

The first step S103A in the steps A and the first step S103B in the steps B, which are illustrated in FIG. 2, are steps for forming physisorption layers from complexing gas on the surface of the film to be treated, and are performed while the temperature of the wafer 2 is kept at a temperature equal to or less than the boiling point of the complexing gas. For example, in a case where the boiling point of a complexing gas is approximately 300° C., the temperature of the wafer 2 is typically set to approximately 250° C. to 280° C., or in a range in which the maximum temperature is approximately 300° C.

For example, 2-cyanophenol is an organic substance having boiling point of approximately 300° C., and is suitable for a complexing gas. In a case of using 2-cyanophenol, a first temperature T1 is desirably set in a range of approximately 200° C. to 280° C., and more desirably in a range of 220° C. to 270° C. When the first temperature T1 falls below 200° C., it takes time to raise the temperature in next step S104A or S104B, and thus, there is a risk that productivity will decrease. Conversely, when the first temperature T1 exceeds 280° C., the adsorption efficiency (an adhesion characteristic) of 2-cyanophenol decreases. Hence, the gas flow rate of 2-cyanophenol must be increased in order to cause a predetermined amount of adsorption in a short length of time, and there is a risk that the amount of gas consumed will increase and thus increase operating costs.

In this manner, after a physisorption layer is formed in step S103A or S103B, the wafer 2 is heated with the IR light emitted from the IR lamp 62, and the temperature thereof is quickly raised to the second temperature in step S104A or S104B. As a result, the adsorption state of the complexing gas on the surface of the film to be treated changes from a physisorption state to a chemisorption state. The temperature is raised in these steps in order to supply activation energy for changing an adsorption state of the complexing gas molecules being adsorbed on the surface of the film to be treated.

The second temperature is determined in consideration of the impact of both the state of the surface of the film to be treated and a characteristic (reactivity) of the complexing gas. In a case where a complexing gas having 2-cyanophenol as a main component, for example, is fed to an Al₂O₃ film which serves as a film to be treated, the second temperature is in a range of approximately 220° C. to 310° C., and appropriate conditions are established in this range by comprehensively considering, for example, a balance between the state of the film to be treated and a third temperature which is described below. In a case of a complexing gas having 2-cyanophenol as a main component, when the second temperature is less than 220° C., the length of time required to perform a conversion to a chemisorption layer lengthens. When the second temperature exceeds 310° C., a conversion to an organometallic complex is also performed without staying in a chemisorption state. In addition, in a case of supplying under reduced pressure, as described below, a temperature at which the organometallic complex starts volatilizing is exceeded, and thus, there is a risk that controllability of the film thickness will decrease.

Next, in the case of the steps B, infrared heating using the IR lamp 62 is further continued while the supplying of the complexing gas is maintained, and at the same time, the power supplied to the IR lamp 62 is increased to raise the temperature to a fourth temperature (step S105B). The fourth temperature is set lower than a temperature at which thermal decomposition of the volatile organometallic complex generated by a reaction between a surface material of the film to be treated and the complexing gas arises, but equal to or greater than a temperature at which sublimation or volatilization starts.

In step S105B, the temperature of the wafer 2 is set to the fourth temperature, and then, the temperature of the wafer 2 is maintained at the fourth temperature T4 for at least a period of time until the supplying of the complexing gas is stopped in step S106B. By virtue of such a flow, the surface of the film to be treated is substantially successively etched in the steps B.

In contrast, in the case of the steps A, as illustrated in step S105A, the supplying of the complexing gas such as 2-cyanophenol is stopped, and the gas inside the treatment chamber 1 is exhausted. Then, as illustrated in step S106A, the IR lamp 62 is used to heat the wafer 2 and raise the temperature thereof to the third temperature. The temperature of the Al₂O₃ film is maintained at the third temperature for a predetermined period of time, whereby the chemisorption layer generated on the surface of the Al₂O₃ film is converted to an organometallic complex.

The third temperature is set to a value within an appropriate range that is equal to or greater than the second temperature but lower than the temperature at which the organometallic complex molecules start volatilizing, and is also set in consideration of, for example, stability of temperature control by the semiconductor manufacturing apparatus 100 or the control unit 40 and temperature measurement accuracy for the wafer 2 or the wafer stage 4 by the thermocouple thermometer 71 or alternative temperature measurement means. In a case of the etching treatment in which an Al₂O₃ film is used as the film to be treated and in which a gas mixture having 2-cyanophenol as a main component is used as the complexing gas, a maximum temperature which is appropriate as the third temperature is approximately 250° C., in the light of the fact that the temperature at which the organometallic complex molecules start volatilizing is approximately 270° C. under a condition of reduced pressure, according to experiments by the inventors.

In addition, the wafer 2 is maintained for the predetermined period of time at the third temperature set in step S106A. Then, in step S107A, the intensity of IR light emitted from the IR lamp 62 is slightly increased to raise the temperature of the wafer 2 to the fourth temperature. The temperature of the wafer 2 is maintained at the fourth temperature T4, whereby the organometallic complex which has been converted from the chemisorption layer is volatilized and removed. At the time when step S107A starts, only one or a few layers, at most five layers, of the organometallic complex have been generated, so that the organometallic complex is quickly volatilized and removed after the temperature reaches the fourth temperature.

When the organometallic complex is volatilized and removed, the reaction for one cycle ends at a time when the film to be treated or a layer of, for example, a silicon compound disposed under the film to be treated is exposed. Note that, in a case of a treatment using, for example, an Al₂O₃ film as the film to be treated and using a gas mixture having 2-cyanophenol as a main component as the complexing gas, a suitable range of the fourth temperature is roughly 270° C. to 400° C. When the temperature is lower than 270° C., there is a risk that the rate of sublimation/volatilization will decrease, impairing treatment efficiency. Conversely, when the temperature is greater than 400° C., there is a risk that part of the organometallic complex will thermally decompose and become a foreign matter in the course of the complex sublimating/volatilizing, adhering to the surface of the wafer 2 or inside the treatment chamber 1.

### First Modification

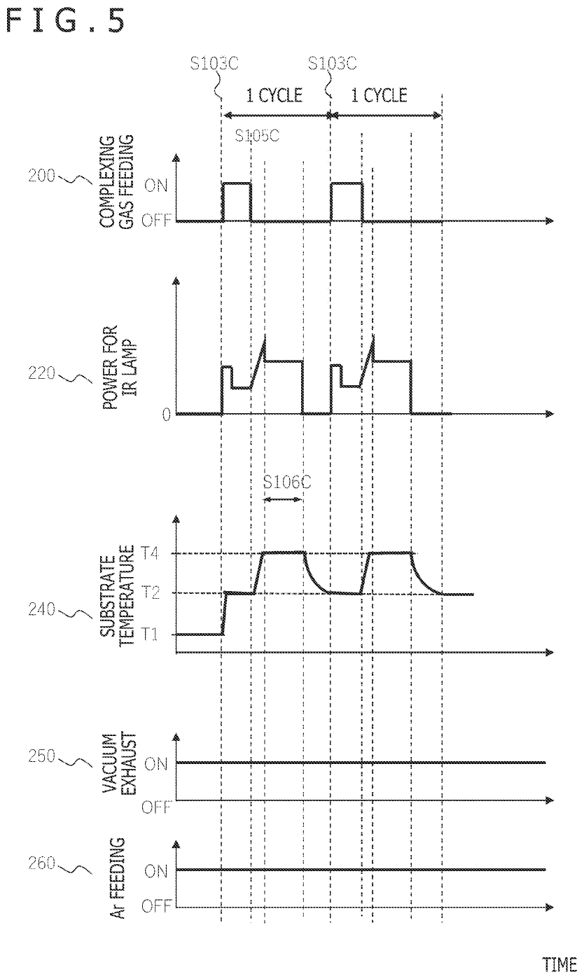

Next, with reference to FIG. 5, a modification of the etching treatment will be described. The modification is different from the above-described embodiment and the first example in that the temperature of the wafer is raised to the second temperature while the complexing gas is being supplied. In the following description, components that are the same or equivalent to those in the above-described embodiment and first example are denoted by the same reference signs, and description thereof is simplified or omitted.

FIG. 5 is a view that illustrates a time chart for a modification performed in the semiconductor manufacturing apparatus.

Similarly to the embodiment illustrated in FIG. 2, steps S101 and S102 are first performed, and a step of detecting the remaining amount of processing for the etching treatment and the comparison of the remaining amount with respect to a threshold are performed. Next, after the control unit 40 determines that the temperature of the wafer 2 is the first temperature, which has been prescribed in advance, or is equal to or less than the first temperature, step S103C is performed. In step S103C, as illustrated in a chart 200, the complexing gas is fed into the treatment chamber 1, and a treatment for forming a physisorption layer in which molecules of the complexing gas are adsorbed on the surface of the film to be treated is started.

Immediately after step S103C starts, as illustrated in a chart 220, power is supplied to the IR lamp 62, and infrared rays are emitted. As a result, the wafer 2 is heated, and the temperature of the wafer 2 is quickly raised to the second temperature T2, as illustrated in a chart 240. As illustrated in the chart 240, during a predefined period of time, the supplying of the complexing gas into the treatment chamber 1 is continued while the temperature of the wafer 2 is maintained at the second temperature. Accordingly, during the step S103C, a reaction in which a physisorption layer of a complexing gas component is formed on the surface of the film to be treated continuously advances, in parallel with a conversion reaction in which the physisorption layer is converted to a chemisorption layer.

As this time, as described above, because the speed of complexing gas molecules diffusing into the film to be treated via the chemisorption layer formed on the surface of the film to be treated is slow, the film thickness of the chemisorption layer is saturated with respect to the treatment time. After the thickness of the chemisorption layer is saturated by performing the treatment in which the supplying of the complexing gas continues for a predetermined length of time while the temperature is roughly maintained at the second temperature T2, the supplying of the complexing gas is stopped in the next step S105C as illustrated in the chart 200.

In the process flow exemplified in FIG. 5, at a stage before performing step S103C for supplying complexing gas, that is, at the time when the temperature of the wafer 2 is the first temperature T1, which has been prescribed in advance, or is equal to or less than the first temperature T1, the pump 15 is driven, and the internal pressure of the treatment chamber 1 is maintained in a reduced-pressure state, as illustrated in a chart 250. Accordingly, when the supplying of the complexing gas is stopped in step S105C, the complexing gas being chemisorbed on the surface remains, but the complexing gas in an unadsorbed state or a physisorption state is entirely exhausted to outside of the treatment chamber 1 and removed. Note that, in order to promote exhausting and removal of the organic gas for etching that is physically adsorbed to, for example, the inner wall of the treatment chamber 1 to outside of the treatment chamber 1, it is desirable to continually supply a small amount of Ar gas into the treatment chamber 1 as illustrated in a chart 260.

The amount of Ar gas to be fed and the pressure in the treatment chamber 1 need to be adjusted as appropriate according to the composition of the film to be treated or the complexing gas. In a case of using a complexing gas having 2-cyanophenol as a main component to etch an Al₂O₃ film, it is desirable that the amount of Ar to be fed be 200 sccm or less and that the pressure inside the treatment chamber be approximately 0.5 to 3.0 Torr. Further, a desirable Ar supply amount is roughly 100 sccm, and the pressure inside the treatment chamber is approximately 1.5 Torr.

Note that, when the Ar supply amount increases beyond 200 sccm, the effective concentration of the complexing gas within the treatment chamber 1 decreases, whereby the adsorption efficiency with respect to the surface of the film to be treated decreases. Thus, there is an increased risk that the etching speed will decrease. In contrast, when the pressure inside the treatment chamber 1 falls below 0.5 Torr, there is a risk that the length of time for the complexing gas to stay within the treatment chamber 1 will shorten and that the efficiency of using the complexing gas will decrease. In order to adjust the pressure inside the treatment chamber such that is exceeds 3 Torr, the Ar supply amount needs to be set to 200 sccm or more. Hence, there is a greater risk that the adsorption efficiency of the complexing gas with respect to the surface of the film to be treated will decrease, decreasing in the etching speed.

Next, as illustrated in the chart 220, infrared heating using the IR lamp 62 is performed to raise the temperature of the wafer 2 to the fourth temperature T4 as illustrated in the chart 240. In the step S106C, the temperature of the wafer 2 is held at roughly the fourth temperature T4 for a predetermined length of time. In the course of the rise in temperature to the fourth temperature T4 and the holding of the temperature, a conversion from the chemisorption layer to the organometallic complex and volatilization and removal of the organometallic complex proceeds. In a case of using an Al₂O₃ film as the film to be treated and a gas having 2-cyanophenol as a main component as the complexing gas, a suitable range of the fourth temperature T4 is 270° C. to 400° C. When the temperature is lower than 270° C., sublimation or volatilization takes a longer time, and a practical etching speed cannot be obtained. Conversely, when he temperature is greater than 400° C., there is a greater risk that part of the organometallic complex will thermally decompose at a location that is equal to or less than 400° C. in the course of sublimation/volatilization of the organometallic complex, and will re-adhere as a foreign matter on the surface of the wafer 2 or inside the treatment chamber 1.

The treatment for volatilization and removal of the organometallic complex ends at a time when the film to be treated or a layer of, for example, a silicon compound disposed under the film to be treated is exposed. Then, as illustrated in the chart 220, when infrared heating using the IR lamp 62 is stopped, the temperature starts decreasing due to heat dissipation from the wafer 2 as illustrated in the chart 240. The temperature of the semiconductor wafer 2 reaches the second temperature T2 or a temperature equal to or less than the second temperature T2, whereby the treatment for one cycle ends.

Then, the treatment in second and subsequent cycles starting from the treatment in S103C after step S102 is repeated a desired number of times, whereby it is possible to perform etching of a predetermined film thickness. The modification illustrated in FIG. 5 is a simplified version of that exemplified in FIG. 4, and the length of time for one cycle is shortened by reducing the number of temperatures to be set and further narrowing a temperature range in the cooling step in S108, which in particular takes time.

### Second Modification

Next, yet another example of the etching treatment of the wafer 2 described above will be described.

On the surface of the wafer 2 used in the present modification, not only a first film to be treated, such as an Al₂O₃ film, that includes a typical metal element and that has been processed into a desired pattern shape, but also a second film to be treated, such as an HfO₂ film, that includes a transition metal element lower than the fifth period of the periodic table is deposited in advance, and part of the film is exposed. In this example, in order to selectively etch the Al₂O₃ film, which serves as the first film to be treated, and the HfO₂ film, which serves as the second film to be treated, a first etching gas for etching only the first film to be treated and a second etching gas for etching only the second film to be treated are selectively used.

Description is given in more detail below. Note that film configurations (such as a film thickness ratio between the first film to be treated and the second film to be treated) described here are merely an example, and the film thickness can be adjusted according to an intended use or a purpose. A laminate composition referred to as Al₂O₃—HfO₂—Al₂O₃ is formed by alternatingly laminating an Al₂O₃ film having a thickness of 2.0 nm as the first film to be treated and an HfO₂ film having a thickness of 5.0 nm as the second film to be treated, and a resist on which a pattern has been formed is disposed on top of the Al₂O₃ film that is the uppermost layer thereof. The films are formed on the surface of the wafer 2 in a state where part of the Al₂O₃ film that is the uppermost layer is exposed from a resist pattern opening.

The wafer 2 that has a laminated film structure including films to be treated as described above is introduced into the treatment chamber 1 and secured by being chucked onto the wafer stage 4, as in the above-described embodiment and first example. In such a state, an amount of etching to be performed on a layer to be treated is determined, and either the steps A or the steps B is selected according to a thickness to be processed. Then, the selected steps are performed. At this time, in a case where only the Al₂O₃ layer or only the HfO₂ layer in laminated films obtained by laminating different kinds of materials is to be selectively etched, a treatment step that use an etching material for etching only an Al₂O₃ film having a thickness of 2.0 nm and a step that use an etching material for etching only the HfO₂ film having a thickness of 5.0 nm are sequentially performed.

An example of a flow of the treatment for etching only an Al₂O₃ film having a thickness of 2.0 nm and only an HfO₂ film having a thickness of 5.0 nm, in this order, will be described below. The Al₂O₃ film to be etched first has a thickness of 2.0 nm, which is a sufficiently large remaining film thickness. Hence, instead of etching one atomic layer at a time, a plurality of layers are continuously etched and removed. In other words, the steps B in FIG. 2 are selected, and the etching treatment starts from step S103B in which the first complexing gas which is suitable for etching the Al₂O₃ film is fed.

For example, 2-cyanophenol is used as the first complexing gas in the present modification. A complexing gas having mainly 2-cyanophenol as an active component is fed to the treatment chamber 1 by the mass flow controller 50-5-1 (not illustrated). At this time, because 2-cyanophenol has low vapor pressure at 100° C. or lower under normal pressure, it is desirable that the supply pipe be heated and that the inside of the pipe be reduced in pressure to approximately 2 kPa or lower. If necessary, it is possible to efficiently supply the complexing gas by combining pieces of vaporization promotion means other than means for reducing pressure or heating, such as means for ultrasonic atomization and means for atomizing a solution obtained by dissolution in an appropriate solvent.

In step S103B, 2-cyanophenol adsorbs to the outermost layer of the Al₂O₃ film to generate an adsorption layer, and steps S104B, S105B, and S106B are sequentially performed, whereby an organic Al complex layer obtained by reaction of the Al₂O₃ with the 2-cyanophenol is generated and is then volatilized and removed. Then, when the Al₂O₃ film is removed by performing the steps B and the steps A a number of times required to remove the Al₂O₃ film of 2.0 nm thickness, the HfO₂ film of 5.0 nm thickness that is the layer thereunder is exposed.

Note that, because the HfO₂ film does not react with 2-cyanophenol, it is possible to completely remove the Al₂O₃ film on the HfO₂ film by repeating only the steps B. In a case of removing the Al₂O₃ film by only the steps B, however, side etching may arise at bottom portions of a resist opening, and a desired pattern shape and pattern dimensions cannot be obtained in some cases. Accordingly, in the present modification, a timing when the steps B end and when the process is switched to the steps A is desirably based on not the remaining film thickness but whether or not at least part of the Al₂O₃ film is removed and part of the HfO₂ film that is at lower layer than the Al₂O₃ film is exposed. However, in the present modification, it can be said that the remaining film thickness of the Al₂O₃ film which is an upper layer is sufficiently small in a state where part of the HfO₂ film which is a lower layer is exposed. Accordingly, it is possible to use the remaining film thickness of the Al₂O₃ at a time when part of the HfO₂ film is exposed, as the threshold in step S102 in FIG. 2.

Next, selective etching of the HfO₂ film is performed. As a second complexing gas, HF and TiCl₄, which are described in Non-Patent Literature 1, are used, for example. It is possible to etch the HfO₂ film by repeating a treatment that includes the following four steps: a step of supplying HF gas from a mass flow controller 50-5-2 (not illustrated) for one second; a step of subsequently supplying nitrogen as a purge gas for 30 seconds; a step of subsequently supplying TiCl₄ from a mass flow controller 50-5-3 (not illustrate) for two seconds; and a step of supplying nitrogen as a purge gas for 30 seconds.

The Al₂O₃ film is not etched under these treatment conditions, but the HfO₂ film is selectively and conformally etched, and thus, etching of the HfO₂ film proceeds in a shape that follows the etching shape of the Al₂O₃ film described above. Because the etching shape of the Al₂O₃ film is processed following the pattern shape of the resist film opening on the uppermost layer, this shape is also transferred to the HfO₂ film. When the treatment is repeated approximately 250 times until the HfO₂ film having a thickness of 5.0 nm is removed in a desired shape, the Al₂O₃ film having a thickness of 2.0 nm at a layer lower than the HfO₂ film is exposed.

In this manner, by appropriately combining and separately using the technique according to the invention of the present application and a publicly-known technique, it is possible to perform high-accuracy selective processing of a multilayer structure. In the present embodiment, there has been described a specific example in which Al₂O₃—HfO₂ having a desired shape can selectively be removed from the upper layer side of an Al₂O₃—HfO₂—Al₂O₃laminated film. In a case where film materials other than the abovementioned film materials are used in combination and where a film thickness to be removed differs from that exemplified above, it is possible to etch even many types of laminated films by selecting an appropriate complexing gas in advance and combining a publicly-known technique if necessary. However, as described above, it is necessary to note that there are constraints on practical use in using many types of etching gases in combination in order to etch one layer in publicly-known techniques.

### [Complexing Gas Components]

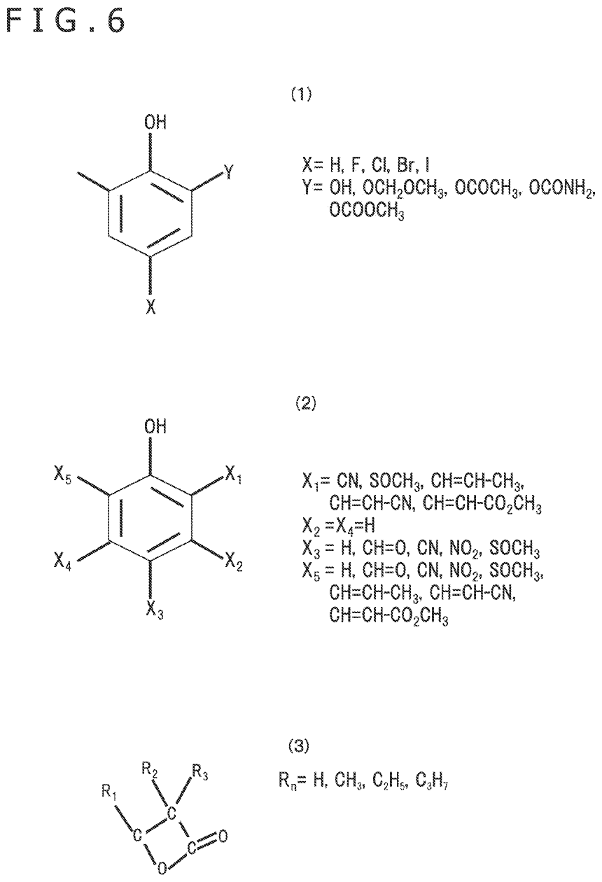

Next, with reference to FIG. 6, components of a complexing gas suitable for the invention of the present application will be described. FIG. 6 is a view that illustrates a molecular structure of components of a complexing gas.

A main active component of the complexing gas is a material that has an interaction in terms of electric charge with respect to positive charge of metal atoms included in a film to be etched. Specifically, the material has a molecular structure that has two atoms (electron-donating atoms) or the atoms at two or more locations, the atom having a lone pair exhibiting an electron-donating action. In the molecular structure, the electron-donating atoms are not directly bonded, and at least one carbon atom is present between the electron-donating atoms (for example, O—C—O instead of O—O).

Note that, when n electrons that exhibits an electron-donating action with respect to positive charge of metal atoms included in a metal film are held, they functions as a replacement for atoms having lone pairs, in some cases. For example, an electron pair on a nitrogen atom in an indole ring is incorporated in a n conjugate of the indole ring as a whole, but the indole ring as a whole exhibits an electron-donating action with respect positive charge of a metal atom. When molecules of the active component of the etching gas have, at two or more locations, a molecular structure that exhibits an electron-donating action with respect to positive charge of metal atoms, electrons are donated to positive charge of a metal element in the film to be etched, to thereby form electron-donating and back-donating strong coordinate bonds and form a thermally stable complex compound.

As concrete examples of materials having such a molecular structure, there are materials having the features of the following molecular structure formulas (1) through (3), for example. A liquid obtained by including at least one type of material having such a molecular structure and, if necessary, dissolving these in an appropriate diluent is used as the chemical liquid 44 which is the raw material for the complexing gas. By use of a liquid dissolved in an appropriate diluent, the diluent promotes vaporization of the active component in the complexing gas, and the vaporized diluent also functions as a carrier gas, whereby smooth supplying becomes possible.

### (Molecular Structure Formula (1))

The molecular structure exemplified in FIG. 6 (1) has a phenol skeleton in which an OH group having a lone pair is bonded to a benzene ring. At a position Y (ortho position) that is adjacent as seen from the carbon atom to which the OH group is bonded, there is one substituent selected as a substituent that exhibits an electron-donating action, from among, for example, an OH group, an OCH₃ group, an OCOCH₃ group, an OCONH₂ group, an NH₂ group, and an N (CH₃)₂ group. In addition, any halogen atom (F, Cl, Br, I) may be bonded to a para position X on the benzene ring, as seen from the carbon atom to which the OH group is bonded.

### (Molecular Structure Formula (2))

The molecular structure exemplified in FIG. 6 (2) has a phenol skeleton in which an OH group, which is a partial structure that exhibits an electron-donating action and has a lone pair, is bonded to a benzene ring. At a position X₁ (ortho position) that is adjacent as seen from the carbon atom to which the OH group is bonded, there is one substituent selected from among, for example, a CN group, a CH═CH—CH₃ group, a CH═CH—CN group, and a CH═CH—CO₂CH₃ group. At a para position X3 on the benzene ring as seen from the carbon atom to which the OH group is bonded, one substituent selected from among, for example, a CH═O group, a CN group, and an NO₂ group may be bonded.

A case of having a CN group at the ortho position is 2-cyanophenol, and a case of having a CH═CH—CO₂CH₃ group at the ortho position is o-hydroxy cinnamate. An electron which functions in an electron-donating fashion as a replacement for an atom having a lone pair is held at an unsaturated bond location in the CN group or the CH═CH—CO₂CH₃ group. In addition, by an inductive electron attraction action held by the CN group or the CH═CH—CO₂CH₃ group, reaction activity by the OH group is increased.

Note that the positions X₂ and X₄ have H. In addition, the position X₅ has one substituent selected from among, for example, H, a CH═O group, a CN group, an NO₂ group, an SOCH₃ group, a CH═CH—CH₃ group, a CH═CH—CN group, and a CH═CH—CO₂CH₃ group.

### (Molecular Structure Formula (3))

The molecular structure exemplified in FIG. 6 (3) is an aliphatic four-membered ring compound having a carbonyl group, the carbonyl group being bonded to an O atom which is a partial structure that has a lone pair. This structure is a material which holds two atoms (electron-donating atoms) that have a lone pair and that exhibit an electron-donating action, that is, the O in the carbonyl group protruding outward from the four-membered ring and the O forming the four-membered ring. In the material, at least one carbon atom is disposed between the electron-donating atoms. As a concrete example, a case where a position R₁ is a methyl group is β-butyrolactone.

The molecular structures exemplified in FIG. 6 (1) or (2) hold atoms or substituents that exhibit an electron-donating action, at at least two locations, and exhibit electrostatic interaction with positive charge held by metal atoms included in the film to be etched, whereby efficient adsorption occurs. By being heated in an adsorption state, two coordinate bonds are generated such that charge mutually cancels out between atoms that exhibit an electron-donating action and the metal atoms included in the film to be etched, whereby an organometallic complex is formed.

As described above, these coordinate bonds are electron-donating and back-donating strong bonds, and moreover, these bonds are formed at two locations. That is, there is a thermally stable complex compound. A metal acetate or metal formate obtained by reacting mere acetic acid or mere formic acid with a typical metal has a bond at one location, and therefore, the stability thereof is not necessarily high. In contrast to this, an organometallic complex that is an intermediate product of the technique of the invention of the present application has remarkably improved thermal stability in comparison to such carboxylates and, as a result, is easily volatilized and removed.

The molecular structure exemplified in FIG. 6 (3) has a smaller molecular cross-sectional area than the molecular structure in FIG. 6 (1) or (2), and thus has a characteristic of easily volatilizing at low temperatures. Hence, vaporization can efficiently be performed even by a vaporizer supply device 47 having a relatively simple structure. When a material having this molecular structure adsorbs to the surface of a film to be etched, by electrostatic interaction with positive charge held by metal atoms included in the film to be etched, the aliphatic four-membered ring is opened, and is then converted to an organometallic complex having a five-membered ring or six-membered ring structure resulting from incorporating the metal element within the ring. The obtained ring-shaped organometallic complex is a thermally stable complex compound and, as a result, is easily volatilized and removed.

### Actions/Effects

In the present embodiment, a treatment gas used in etching is one type of organic gas. Accordingly, it is possible to manufacture a semiconductor device without requiring a complicated gas supplying system. In addition, because there is also no need to, for example, replace gases, etching efficiency is not reduced. In addition, a compound has a property of having high thermal stability, and thus does not become a foreign matter during exhausting.

Accordingly, by virtue of the present embodiment, it is possible to provide a method of manufacturing a semiconductor device and a semiconductor manufacturing apparatus that can ensure treatment efficiency and suppress the occurrence of foreign matters, without requiring a complex gas supplying system.

The embodiment of the present invention has been described above. However, the present invention is not limited to the embodiment described above, and various modifications are possible within a range that does not deviate from the gist of the present invention.

### REFERENCE SIGNS LIST

1: Treatment chamber
2: Semiconductor wafer
3: Discharge region
4: Wafer stage
5: Shower plate
6: Top plate
11: Base chamber
12: Quartz chamber
14: Pressure-adjustment mechanism
15: Pump
16: Vacuum exhaust pipe
17: Gas dispersion plate
20: High-frequency power supply
22: Matcher
30: Electrostatic chucking electrode
31: Electrostatic chucking power supply
34: ICP coil
38: Chiller
39: Flow path
40: Control unit
41: Calculation section
45: Tank
46: Heater
47: Vaporizer supply device
50-1 through 50-5: Mass flow controller
51: Integrated mass flow controller control unit
52, 53, 54: Valve
60: Container
62: IR lamp
63: Reflective plate
64: IR lamp power supply
70: Thermocouple
71: Thermocouple thermometer
74: IR-light-transmissive window
75: Gas flow path
78: Slit plate
81: O-ring
92: Optical fiber
93: External IR light source
94: Optical path switch
95: Optical distributor
96: Spectrometer
97: Detector
98: Optical multiplexer
100: Semiconductor manufacturing apparatus

1. A method of manufacturing a semiconductor device, the method comprising:
a step of comparing a remaining amount of processing for a film to be treated that is formed on a semiconductor wafer, with a threshold;
a step of forming a compound made from the film to be treated and an organic gas by heating the semiconductor wafer while supplying the organic gas, the organic gas including a material having, within a molecule, at least two substituents that hold a lone pair; and
a step of causing the compound to desorb from a surface of the semiconductor wafer by, on a basis of a result of the step of comparing, further heating the semiconductor wafer after the step of forming the compound, to raise a temperature of the semiconductor wafer to a predetermined temperature.

2. The method of manufacturing a semiconductor device according to claim 1, wherein
the step of causing the compound to desorb is a step of, in a case where the remaining amount of processing is equal to or less than the threshold, heating the semiconductor wafer in a plurality of stages after the supplying of the organic gas is stopped, to raise the temperature of the semiconductor wafer to the predetermined temperature.

3. The method of manufacturing a semiconductor device according to claim 1, wherein
the step of causing the compound to desorb is a step of, in a case where the remaining amount of processing is greater than the threshold, continuously heating the semiconductor wafer while supplying the organic gas, to raise the temperature of the semiconductor wafer to the predetermined temperature.

4. The method of manufacturing a semiconductor device according to claim 1, wherein
the step of causing the compound to desorb includes
a first desorption step of, in a case where the remaining amount of processing is equal to or less than the threshold, causing the compound to desorb by heating the semiconductor wafer in a plurality of stages after the supplying of the organic gas is stopped, to raise the temperature of the semiconductor wafer to the predetermined temperature, and
a second desorption step of, in a case where the remaining amount of processing is greater than the threshold, causing the compound to desorb by continuously heating the semiconductor wafer while supplying the organic gas, to raise the temperature of the semiconductor wafer to the predetermined temperature, and
the step of forming the compound, the first desorption step, and the second desorption step are performed until the remaining amount of processing disappears.

5. The method of manufacturing a semiconductor device according to claim 1, wherein
the organic gas has a phenol skeleton and has, at an adjacent position as seen from a carbon atom to which an OH group is bonded, any one substituent from among an OH group, an OCH₃ group, an OCOCH₃ group, an OCONH₂ group, an NH₂ group, and an N (CH₃)₂ group.

6. The method of manufacturing a semiconductor device according to claim 1, wherein
the organic gas has a phenol skeleton and has, at an adjacent position as seen from a carbon atom to which an OH group is bonded, any one substituent from among a CN group, a CH═CH—CH₃ group, a CH═CH—CN group, and a CH═CH—CO₂CH₃ group.

7. The method of manufacturing a semiconductor device according to claim 6, wherein
the organic gas includes 2-cyanophenol or o-hydroxy cinnamate.

8. The method of manufacturing a semiconductor device according to claim 1, wherein
the organic gas is an aliphatic four-membered ring compound having a carbonyl group and has, as electron-donating atoms, an O atom in the carbonyl group and an O atom forming a four-membered ring, and at least one carbon atom is disposed on the O atoms.

9. The method of manufacturing a semiconductor device according to claim 8, wherein
the organic gas includes B-butyrolactone.

10. A semiconductor manufacturing apparatus, comprising:
a vacuum container having a treatment chamber therein;
a stage that is disposed within the treatment chamber and that has a top surface on which a semiconductor wafer having, on a surface thereof, a film to be treated is placed;
a treatment gas supply device configured to supply an organic gas into the treatment chamber;
an exhaust device configured to exhaust the gas inside the treatment chamber;
a heater configured to heat the semiconductor wafer to raise a temperature of the semiconductor wafer to a predetermined temperature; and
a control unit, wherein
the organic gas has, within a molecule, at least two substituents that hold a lone pair, and
the control unit controls
a step of comparing a remaining amount of processing for the film to be treated, with a threshold,
a step of forming a compound made from the film to be treated and the organic gas by heating the semiconductor wafer while supplying the organic gas to the treatment chamber, the organic gas including a material having, within a molecule, at least two substituents that hold a lone pair, and
a step of causing the compound to desorb from the surface of the semiconductor wafer by, on a basis of a result of the step of comparing, further heating the semiconductor wafer after the step of forming the compound, to raise the temperature of the semiconductor wafer to the predetermined temperature.

11. The semiconductor manufacturing apparatus according to claim 10, wherein
the step of causing the compound to desorb includes a step of, in a case where the remaining amount of processing is equal to or less than the threshold, heating the semiconductor wafer in a plurality of stages after the supplying of the organic gas is stopped, to raise the temperature of the semiconductor wafer to the predetermined temperature.

12. The semiconductor manufacturing apparatus according to claim 10, wherein
the step of causing the compound to desorb includes a step of, in a case where the remaining amount of processing is greater than the threshold, continuously heating the semiconductor wafer while supplying the organic gas to the treatment chamber, to raise the temperature of the semiconductor wafer to the predetermined temperature.
